(19) United States
(12) Patent Application Publication
(10) Pub. No.: US 2023/0209864 A1
(43) Pub. Date: Jun. 29, 2023

(54) DISPLAY APPARATUS

(71) Applicant: LG Display Co., Ltd., Seoul (KR)

(72) Inventors: Dohong KIM, Paju-si (KR); Saemleenuri LEE, Paju-si (KR); Seokwon JI, Paju-si (KR)

(73) Assignee: LG Display Co., Ltd., Seoul (KR)

(21) Appl. No.: 18/077,724

(22) Filed: Dec. 8, 2022

(30) Foreign Application Priority Data
Dec. 29, 2021 (KR) 10-2021-0191001

(51) Int. Cl. H01L 51/00

(52) U.S. Cl. CPC H01L 51/5225; H01L 27/3276; H01L 51/5234; H01L 27/3246

(57) ABSTRACT

A display apparatus can include a plurality of subpixels disposed on a substrate, each of the subpixels including first and second light emission areas and a non-light emission area disposed between the first and second light emission areas. One of the plurality of subpixels can include an anode electrode disposed on the substrate and including first and second divided electrodes, a light emitting element disposed on the anode electrode in the first and second light emission areas, a bank disposed on the anode electrode in the non-light emission area, and a cathode electrode disposed on the light emitting element and the bank. The first divided electrode is disposed in the first light emission area, and the second divided electrode is disposed in the second light emission area.

### CROSS-REFERENCE TO RELATED APPLICATIONS

This application claims priority to Korean Patent Application No. 10-2021-0191001 filed on Dec. 29, 2021 in the Republic of Korea, the entire contents of which are hereby expressly incorporated by reference into the present application.

### BACKGROUND

### Technical Field

The present disclosure relates to a display apparatus.

### Discussion of the Related Art

With the advancement of the information age, a demand for a display apparatus for displaying an image has increased in various forms. Therefore, various types of display apparatuses such as a liquid crystal display (LCD) apparatus, a plasma display panel (PDP) apparatus, and an electroluminescence display (ELD) apparatus have been recently used. The electroluminescence display (ELD) apparatus can include an organic light emitting display (OLED) apparatus and a quantum-dot light emitting display (QLED) apparatus.

Among the display apparatuses, the electroluminescence display apparatus is a self-light emitting type and has advantages in that a viewing angle and a contrast ratio of the display apparatus are more excellent than those of the liquid crystal display (LCD) apparatus. Further, since the electroluminescence display apparatus does not require a separate backlight, it is advantageous that the electroluminescence display apparatus can be made thin and lightweight and has low power consumption. Further, the electroluminescence display apparatus has advantages in that it can be driven at a direct current low voltage, has a fast response speed, and especially has a low manufacturing cost.

In the process of manufacturing the electroluminescent display apparatus, when a light emitting element is deposited on an anode, external particles can be seated on the anode. In this case, the light emitting element and a cathode are deposited on the particles without continuity, and the anode and the cathode can be in contact with each other. Therefore, a pixel may not be normally manufactured, whereby an issue can occur in that dark spots can be formed. In the related art, a method of normalizing dark spots by applying a high voltage pulse to an end of a cathode, which is in contact with an anode, to space the end of the cathode apart from the anode, can be used to address this issue.

When the electroluminescence display apparatus is provided in a bottom emission mode in which light is emitted in a lower direction, the cathode is made of a metal material, so that the cathode positioned in an area adjacent to the particles can be oxidized to non-conductorize a surface of the cathode, whereby dark spots can be normalized.

### SUMMARY OF THE DISCLOSURE

When an electroluminescence display apparatus is provided in a top emission mode in which light is emitted in an upper direction, a cathode can be made of a transparent conductive material. In this case, the inventors of the present disclosure have recognized that, since it is difficult to non-conductorize the surface of the cathode positioned in the area adjacent to the particles, the possibility that the dark spots will be normalized may become lowered. Therefore, even though a process of normalizing the dark spots is performed, there can be a limitation in that some dark spots still can exist without being normalized.

Accordingly, the present disclosure is directed to a light emitting display apparatus that substantially obviate one or more of the issues due to limitations and disadvantages of the related art.

The present disclosure has been formed in view of the above issues and other limitations associated with the related art, and it is an object of the present disclosure to provide a light emitting display apparatus that normalizes a subpixel into which particles are introduced through a coating layer.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a display apparatus comprising a plurality of subpixels provided on a substrate, each including first and second light emission areas and a non-light emission area disposed between the first and second light emission areas, wherein one of the plurality of subpixels includes an anode electrode disposed on the substrate, including first and second divided electrodes, a light emitting element provided on the anode electrode in the first and second light emission areas, a bank provided on the anode electrode in the non-light emission area, and a cathode electrode disposed on the light emitting element and the bank, and the first divided electrode is provided in the first light emission area, and the second divided electrode is provided in the second light emission area.

It is to be understood that both the foregoing general description and the following detailed description are exemplary and explanatory and are intended to provide further explanation of the inventive concepts as claimed.

### BRIEF DESCRIPTION OF THE DRAWINGS

The above and other objects, features and other advantages of the present disclosure will be more clearly understood from the following detailed description taken in conjunction with the accompanying drawings, in which:

FIGS. 1A and 1B are plan views illustrating one subpixel of a light emitting display apparatus according to an embodiment of the present disclosure;

FIGS. 2A to 2C are cross-sectional views taken along line A-A′ shown in FIG. 1, illustrating a process of manufacturing a light emitting display apparatus according to an embodiment of the present disclosure;

FIGS. 3A to 3C are cross-sectional views taken along line B-B′ shown in FIG. 1, illustrating a process of manufacturing a light emitting display apparatus according to an embodiment of the present disclosure; and

FIG. 4 is a cross-sectional view illustrating a light emitting display apparatus according to another embodiment of FIG. 3C.

### DETAILED DESCRIPTION OF THE EMBODIMENTS

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description thereof will be omitted. In a case where ‘comprise’, ‘have’ and ‘include’ described in the present disclosure are used, another portion can be added unless ‘only’ is used. The terms of a singular form can include plural forms unless referred to the contrary.

In construing an element, the element is construed as including an error range although there is no explicit description.

In describing a position relationship, for example, when the position relationship is described as ‘upon’, ‘above’, ‘below’ and ‘next to’, one or more portions can be arranged between two other portions unless ‘just’ or ‘direct’ is used.

In describing a temporal relationship, for example, when the temporal order is described as ‘after’, ‘subsequent’, ‘next’ and ‘before’, a case which is not continuous can be included unless ‘just’ or ‘direct’ is used.

It will be understood that, although the terms “first,” “second,” etc. can be used herein to describe various elements, these elements should not be limited by these terms. These terms are only used to distinguish one element from another, and may not define any order or sequence. For example, a first element could be termed a second element, and, similarly, a second element could be termed a first element, without departing from the scope of the present disclosure.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, various embodiments of the present disclosure will be described with reference to the drawings. All the components of each light emitting display apparatus according to all embodiments of the present disclosure are operatively coupled and configured.

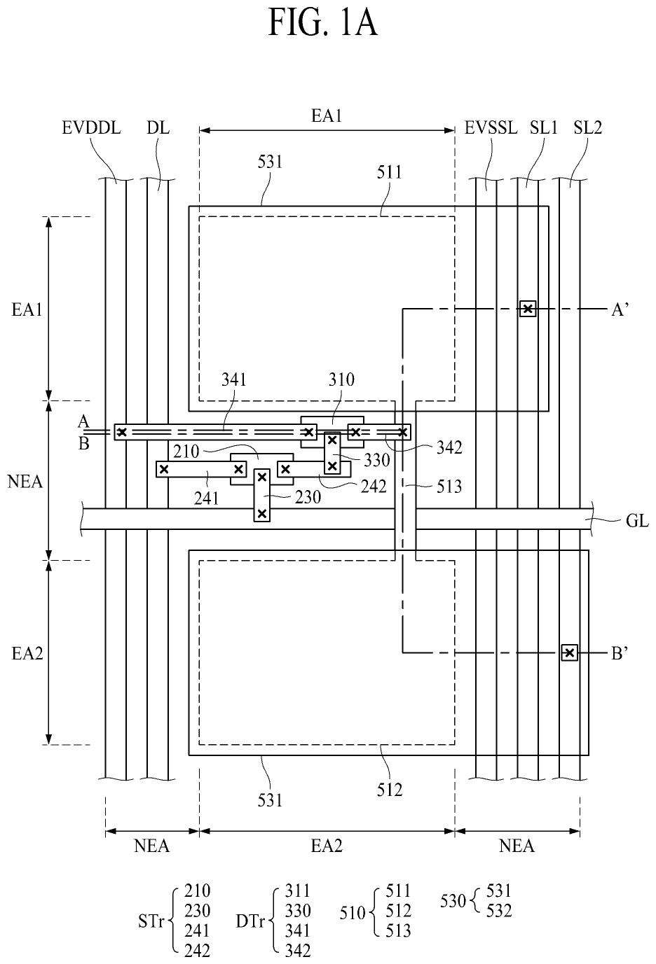

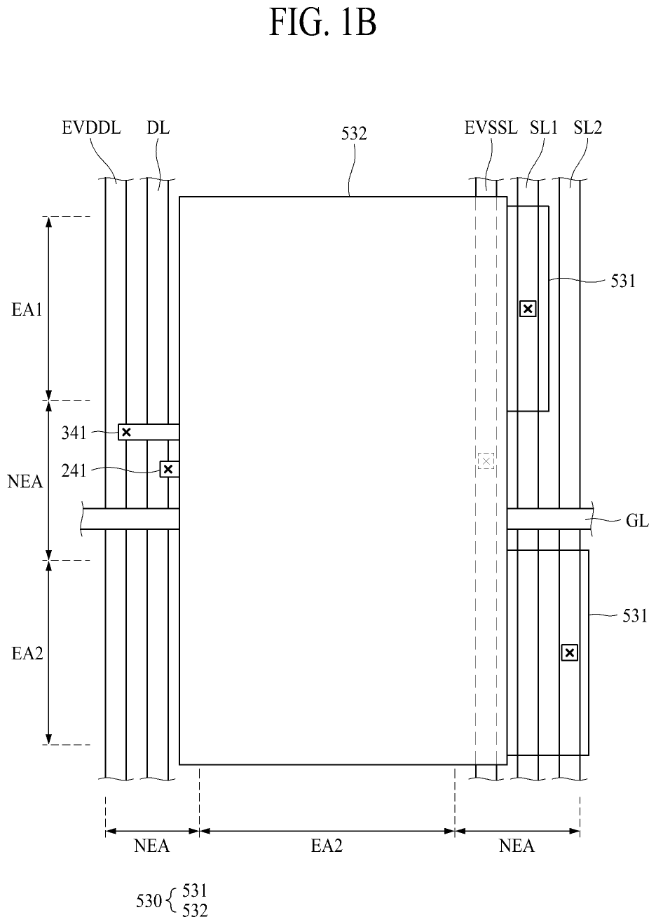

FIGS. 1A and 1B are plan views illustrating one subpixel of a light emitting display apparatus according to an embodiment of the present disclosure.

Referring to FIGS. 1A and 1B, the light emitting display apparatus according to the embodiment of the present disclosure can include a substrate 100, a high potential power voltage line EVDDL, a low potential power voltage line EVSSL, a gate line GL, a data line DL, first and second sensing lines SL1 and SL2, a switching thin film transistor STr, a driving thin film transistor DTr, an anode electrode 510 and a cathode electrode 530.

The substrate 100 can be made of glass or plastic, but is not limited thereto. The substrate 100 can be made of a semiconductor material such as a silicon wafer.

A plurality of subpixel areas defined by a gate line GL arranged in one direction, a data line DL arranged to be perpendicular to the gate line GL and a high potential power voltage line EVDDL and a low potential power voltage line EVSSL, which are arranged to be parallel with the data line DL, are provided on the substrate 100. One subpixel is shown in FIGS. 1A and 1B, and each subpixel can include first and second light emission areas EA1 and EA2 and a non-light emission area NEA disposed between the first and second emission areas EA1 and EA2. For example, the non-light emission area NEA can be disposed to surround each of the first and second emission areas EA1 and EA2. A size of the first light emission area EA1 and a size of the second light emission area EA2 can be the same as each other. In addition, the first and second sensing lines SL1 and SL2 are provided to be parallel with the data line DL.

The switching thin film transistor STr is disposed in an area where the gate line GL and the data line DL cross each other. The switching thin film transistor STr can serve as a switching element for applying a signal to the subpixel.

The switching thin film transistor STr can include a semiconductor layer 210, a gate insulating layer 220, a gate electrode 230, a source electrode 241 and a drain electrode 242. The switching thin film transistor STr can be connected to the gate line GL and the data line DL. For example, the gate electrode 230 of the switching thin film transistor STr can be connected to the gate line GL, and the source electrode 241 of the switching thin film transistor STr can be connected to the data line DL.

One side of the semiconductor layer 210 of the switching thin film transistor STr can be connected to the source electrode 241 of the switching thin film transistor STr through a contact hole, and the other side of the semiconductor layer 210 can be connected to the drain electrode 242 of the switching thin film transistor STr through the contact hole.

The switching thin film transistor STr can be turned on or off by a scan signal supplied through the gate line GL. Therefore, when a data voltage is supplied through the data line DL, the switching thin film transistor STr can control that the data voltage is applied to the subpixel through the scan signal.

The driving thin film transistor DTr serves to drive the subpixel based on the signal applied by the switching thin film transistor STr. Referring to FIGS. 1A and 1B, the gate electrode 330 of the driving thin film transistor DTr can be connected to the drain electrode 242 of the switching thin film transistor STr through the contact hole. In addition, the source electrode 341 of the driving thin film transistor DTr can be connected to the high potential power voltage line EVDDL, and the drain electrode 342 of the driving thin film transistor DTr can be connected to the anode electrode 510 through the contact hole.

One side of the semiconductor layer 310 of the driving thin film transistor DTr can be connected to the source electrode 341 of the driving thin film transistor DTr through the contact hole, and the other side of the semiconductor layer 310 of the driving thin film transistor DTr can be connected to the drain electrode 342 of the driving thin film transistor DTr through the contact hole.

The anode electrode 510 is provided on the switching thin film transistor STr and the driving thin film transistor DTr. The anode electrode 510 can be a single layer or multi-layer made of a metal material such as molybdenum (Mo) or titanium (Ti) or their alloy, or can be made of a transparent conductive material such as indium tin oxide (ITO) or indium zinc oxide (IZO).

The anode electrode 510 can include a first divided electrode 511, a second divided electrode 512 and a connection portion 513. The first divided electrode 511 can be provided in a first light emission area EA1, and the second divided electrode 512 can be provided in a second light emission area EA2. The first divided electrode 511 and the second divided electrode 512 can be formed at the same size. In addition, the connection portion 513 can be formed between the first divided electrode 511 and the second divided electrode 512 to electrically connect the first divided electrode 511 with the second divided electrode 512. The connection portion 513 can be provided in the non-light emission area NEA, and can be provided with a contact hole electrically connected to the drain electrode 342 of the driving thin film transistor, but is not limited thereto. For example, the drain electrode 342 of the driving thin film transistor DTr can be electrically connected to the first divided electrode 511 or the second divided electrode 512 through the contact hole.

The cathode electrode 530 is provided on the anode electrode 510. The cathode electrode 530 can include a first cathode electrode 531 and a second cathode electrode 532 provided on the first cathode electrode 531. When the light emitting display apparatus of the present disclosure is provided in a top emission mode, the cathode electrode 530 can be made of a transparent conductive material such as indium tin oxide (ITO) or indium zinc oxide (IZO) so as to transmit light emitted from a light emitting element 520 toward an upper direction.

The first cathode electrode 531 can be provided on the anode electrode 510, and can be divided into a plurality of areas. For example, one first cathode electrode 531 can be formed to overlap the first divided electrode 511 in the first light emission area EA1, and the other first cathode electrode 531 can be formed to overlap the second divided electrode 512 in the second light emission area EA2. In addition, the first cathode electrodes 531 respectively provided in the first and second light emission areas EA1 and EA2 are not in contact with each other, and may not be electrically connected to each other.

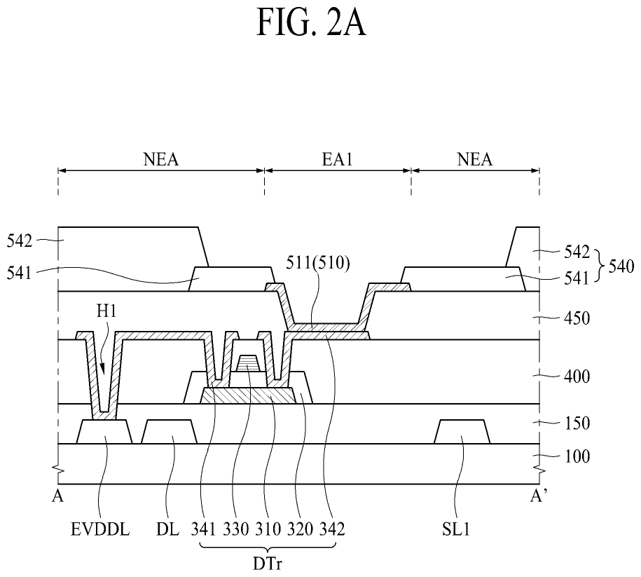

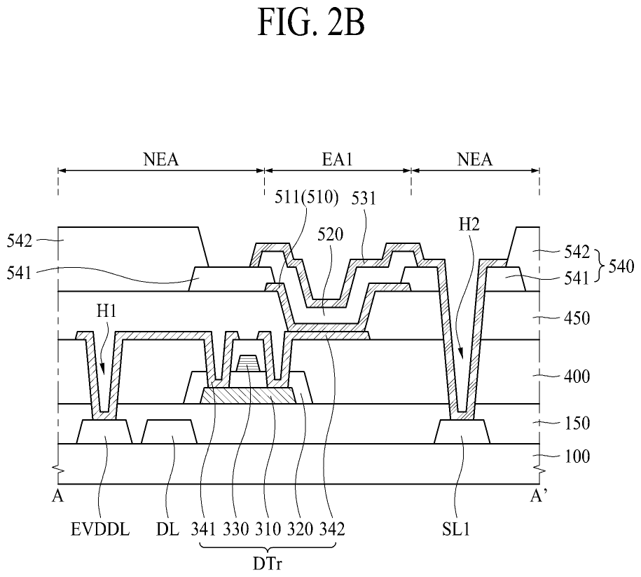

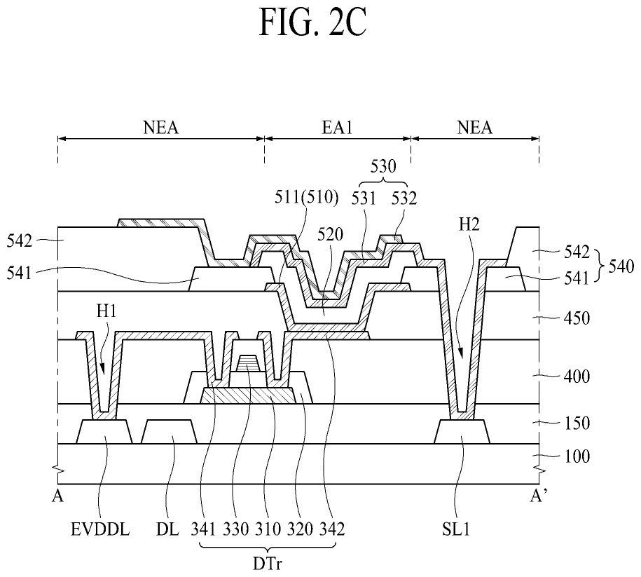

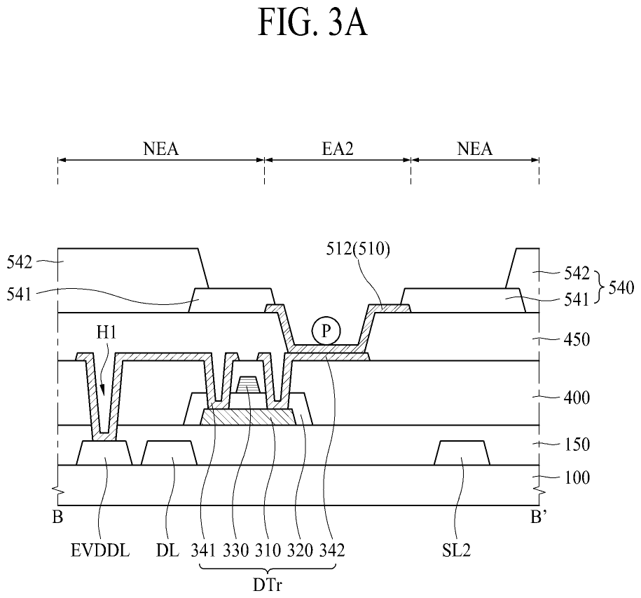

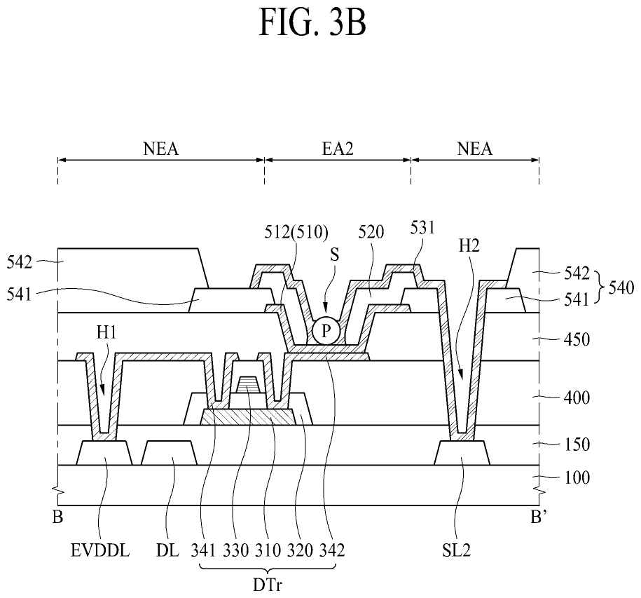

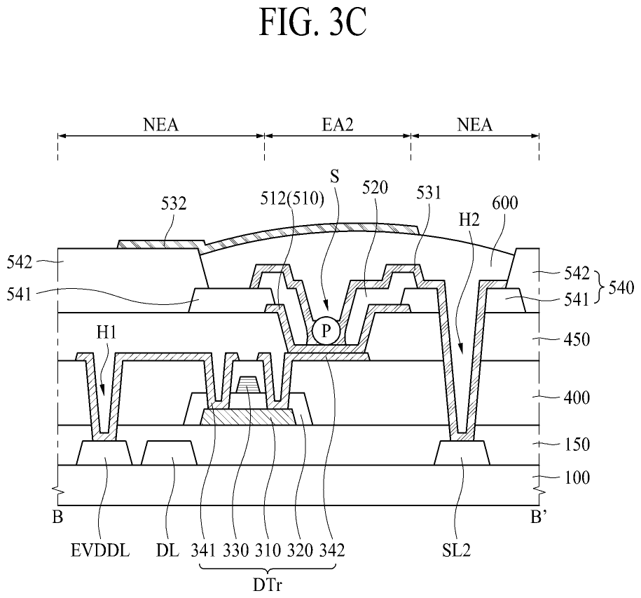

The first cathode electrode 531 provided in the first light emission area EA1 can be extended in a direction in which the first sensing line SL1 is provide, so as to overlap the first sensing line SL1. In addition, the first cathode electrode 531 provided in the second light emission area EA2 can be extended in a direction in which the second sensing line SL2 is provided, so as to overlap the second sensing line SL2. Further, the first cathode electrode 531 provided in the first light emission area EA1 can be electrically connected to the first sensing line SL1 through the contact hole, and the first cathode electrode 531 provided in the second light emission area EA2 can be electrically connected to the second sensing line SL2 through the contact hole. Therefore, it is possible to check whether each of the first and second light emission areas EA1 and EA2 is normally driven, through the first and second sensing lines SL1 and SL2, and this will be described in detail with reference to FIGS. 2A to 3C.

The second cathode electrode 532 is provided on the first cathode electrode 531. The second cathode electrode 532 can be formed as one surface to overlap the first cathode electrode 531 provided in each of the first and second light emission areas EA1 and EA2. In addition, the second cathode electrode 532 can be extended in a direction in which the low potential power voltage line EVSSL is provided, so as to overlap the low potential power voltage line EVSSL. The second cathode electrode 532 can be electrically connected to the low potential power voltage line EVSSL through the contact hole. The second cathode electrode 532 may not overlap the first and second sensing lines SL1 and SL2, and may not be electrically connected thereto.

FIGS. 2A to 2C are cross-sectional views taken along line A-A′ shown in FIG. 1, illustrating a process of manufacturing a light emitting display apparatus according to an embodiment. Further, FIG. 2A to FIG. 2C only show that the first light emission area EA1 is normally driven.

Referring to FIG. 2A, a high potential power voltage line EVDDL, a data line DL, a first sensing line SL1, a buffer layer 150, a driving thin film transistor DTr, an anode electrode 510 and a bank 540 can be formed on a substrate 100.

The substrate 100 can be made of glass or plastic, but is not limited thereto. The substrate 100 can be made of a semiconductor material such as a silicon wafer.

The high potential power voltage line EVDDL, the data line DL and the first sensing line SL1 are provided on the substrate 100. As described above with reference to FIGS. 1A and 1B, the high potential power voltage line EVDDL can be electrically connected to the source electrode 341 of the driving thin film transistor DTr to supply a high potential power voltage. The data line DL can be electrically connected to the source electrode 241 of the switching thin film transistor STr to supply a data voltage. Further, the first sensing line SL1 is electrically connected to the first cathode electrode 531 through the second contact hole H2 to check whether the first light emission area EA1 is normally driven.

The buffer layer 150 is provided on the high potential power voltage line EVDDL, the data line DL and the first sensing line SL1. The buffer layer 150 can be comprised of a single layer of silicon nitride (SiNx) or silicon oxide (SiOx), or a multi-layer of silicon nitride (SiNx) and silicon oxide (SiOx). The buffer layer 150 can insulate the high potential power voltage line EVDDL, the data line DL and the first sensing line SL1, and can compensate for a step difference between the substrate 100 and the high potential power voltage line EVDDL, the data line DL and the first sensing line SL1.

The driving thin film transistor DTr is provided on the buffer layer 150. The driving thin film transistor DTr can include a semiconductor layer 310, a gate insulating layer 320, a gate electrode 330, a source electrode 341 and a drain electrode 342.

The semiconductor layer 310 of the driving thin film transistor DTr is provided on the buffer layer 150. The semiconductor layer 310 can include a metal oxide such as polysilicon or indium-zinc-oxide (IZO), indium-gallium-tin-oxide (IGTO) and indium-gallium-oxide (IGO).

The gate insulating layer 320 of the driving thin film transistor DTr can be provided on the semiconductor layer 310 to insulate the gate electrode 330 from the semiconductor layer 310. The gate insulating layer 320 of the driving thin film transistor DTr can be comprised of a single layer of silicon nitride (SiNx) or silicon oxide (SiOx), or a multi-layer of silicon nitride (SiNx) and silicon oxide (SiOx).

The gate electrode 330 of the driving thin film transistor DTr is provided on the gate insulating layer 320. The gate electrode 330 can be formed on the gate insulating layer 320 to overlap a channel area of the semiconductor layer 310.

An interlayer insulating layer 400 is provided on the gate insulating layer 320 and the gate electrode 330 of the driving thin film transistor. The interlayer insulating layer 400 can be comprised of a single layer of silicon nitride (SiNx) or silicon oxide (SiOx), or a multi-layer of silicon nitride (SiNx) and silicon oxide (SiOx).

A contact hole for exposing the semiconductor layer 310 of the driving thin film transistor DTr can be formed in the gate insulating layer 320 and the interlayer insulating layer 400.

The source electrode 341 and the drain electrode 342 of the driving thin film transistor DTr are provided on the interlayer insulating layer 400 while facing each other. Further, each of the source electrode 341 and the drain electrode 342 of the driving thin film transistor DTr can be connected to the semiconductor layer 310 through a contact hole formed in the gate insulating layer 320 and the interlayer insulating layer 400.

A first contact hole H1 passing through the buffer layer 150 and the interlayer insulating layer 400 can be formed to expose the high potential power voltage line EVDDL. The source electrode 341 of the driving thin film transistor DTr can be extended in a direction in which the first contact hole H1 is formed, and can be electrically connected to the high potential power voltage line EVDDL through the first contact hole H1. A lower surface of the first contact hole H1 exposes the high potential power voltage line EVDDL, and an inner surface of the first contact hole H1 is comprised of sides of the buffer layer 150 and the interlayer insulating layer 400.

A planarization layer 450 is provided on the interlayer insulating layer 400. The planarization layer 450 can compensate for a step difference due to the driving thin film transistor DTr and the contact holes. The planarization layer 450 can be made of an inorganic insulating material or an organic insulating material. Alternatively, the planarization layer 450 can be formed as a layer made of an organic insulating material and a layer made of an inorganic insulating material are stacked.

The anode electrode 510 can be provided on the planarization layer 450, and can be electrically connected to the drain electrode 342 of the driving thin film transistor DTr. As described above with reference to FIGS. 1A and 1B, the anode electrode 510 includes first and second divided electrodes 511 and 512. However, since FIGS. 2A to 2C show the first light emission area EA1, the first divided electrode 511 is only shown.

The first divided electrode 511 can be a single layer or multi-layer made of a metal material, such as molybdenum (Mo) or titanium (Ti), or their alloy, or can be made of a transparent conductive material such as indium tin oxide (ITO) or indium zinc oxide (IZO).

The bank 540 is formed on the first divided electrode 511 to define the first light emission area EA1 and the non-light emission area NEA. For example, an area in which the bank 540 is not formed can be the first light emission area EA1, and an area in which the bank 540 is formed can be the non-light emission area NEA.

The bank 540 can be formed of an organic layer such as an acrylic resin, an epoxy resin, a phenolic resin, a polyamide resin and a polyimide resin. Alternatively, the bank 540 can be formed of an inorganic layer such as silicon nitride, aluminum nitride, zirconium nitride, titanium nitride, hafnium nitride, tantalum nitride, silicon oxide, aluminum oxide or titanium oxide.

The bank 540 can include first and second banks 541 and 542. The first bank 541 can be formed on the first divided electrode 511. The first bank 541 can be formed to cover an end of the first divided electrode 511 and surround the first divided electrode 511. In addition, the first bank 541 can be formed to cover the planarization layer 450 to reach an outer area rather than the position where the first sensing line SL1 is formed.

The second bank 542 can be formed to surround the first bank 541. In FIG. 2A, the second bank 542 is formed to cover the end of the first bank 541, but is not limited thereto. For example, the second bank 542 can be formed to be in contact with a side of the first bank 541, but can be formed so as not to cover the upper surface of the first bank 541. Further, since the second bank 542 is formed in the outer area rather than the first bank 541, the second bank 542 may not overlap the first sensing line SL1.

A height of the second bank 542 can be higher than that of the first bank 541. In addition, when the first and second banks 541 and 542 are made of the same material, the bank 540 is not divided into the first and second banks 541 and 542, and can be viewed as one bank having a step difference.

Referring to FIG. 2B, a light emitting element 520 and a first cathode electrode 531 can be formed on the first divided electrode 511 and the bank 540.

The light emitting element 520 is provided on the first divided electrode 511. The light emitting element 520 can be formed on the first bank 541. For example, the light emitting element 520 can be formed in the first light emission area EA1 and the non-light emission area NEA.

The light emitting element 520 can include a hole transporting layer, a light emitting layer and an electron transporting layer. In this case, when a voltage is applied to the anode electrode 510 and the cathode electrode 530, holes and electrons move to the light emitting element through the hole transporting layer and the electron transporting layer, respectively, and are combined with each other in the light emitting element.

The light emitting element 520 can be provided to emit white light. To this end, the light emitting element 520 can include a plurality of stacks for emitting light of different colors.

The first cathode electrode 531 can be provided on the light emitting element 520, and can be formed on the first bank 541. In the same manner as the light emitting element 520, the first cathode electrode 531 is also formed in the first light emission area EA1 and the non-light emission area NEA.

When the light emitting display apparatus of the present disclosure is provided in a top emission mode, the first cathode electrode 531 is made of a transparent conductive material such as indium tin oxide (ITO) or indium zinc oxide (IZO) so as to transmit light emitted from the light emitting element 520 toward an upper direction.

In order to expose the first sensing line SL1, a second contact hole H2 passing through the buffer layer 150, the interlayer insulating layer 400, the planarization layer 450 and the first bank 541 can be formed. The first cathode electrode 531 can be extended in a direction in which the second contact hole H2 is formed, and can be electrically connected to the first sensing line SL1 through the second contact hole H2. A lower surface of the second contact hole H2 exposes the first sensing line SL1, and an inner surface of the second contact hole H2 is comprised of sides of the buffer layer 150, the interlayer insulating layer 400, the planarization layer 450 and the first bank 541.

Through the first sensing line SL1 electrically connected to the first cathode electrode 531, it is possible to check whether the first light emission area EA1 is normally driven. In detail, a voltage higher than a high potential power voltage supplied to the high potential power voltage line EVDDL can be supplied to the first sensing line SL1. In this case, since a higher voltage is supplied to the first cathode electrode 531 connected to the first sensing line SL1 rather than the first divided electrode 511 connected to the high potential power voltage line EVDDL, a voltage can be supplied to the light emitting element 520 in a reverse direction. When a voltage is supplied in a reverse direction, a current does not flow in the light emitting element 520 which is normally driven, whereby the light emitting element 520 does not emit light.

Since FIG. 2B of the present disclosure discloses a structure in which the light emitting element 520 and the first cathode electrode 531 are normally formed on the first divided electrode 511, the first light emission area EA1 does not emit light. For example, a reverse voltage can be supplied to the light emitting element 520 through the first sensing line SL1, so that it is possible to check whether the first light emission area EA1 is normally driven by sensing the current flowing to the first light emission area EA1.

As shown in FIG. 2C, when the first light emission area EA1 is normally driven, the second cathode electrode 532 can be formed.

The second cathode electrode 532 can be provided on the first cathode electrode 531, and can be also provided on the first and second banks 541 and 542. However, the second cathode electrode 532 may not be formed inside the second contact hole H2. As described above with reference to FIGS. 1A and 1B, the second cathode electrode 532 can be electrically connected to the low potential power voltage line EVSSL to receive a low potential power voltage.

When the light emitting display apparatus of the present disclosure is provided in a top emission mode, the second cathode electrode 532 is made of a transparent conductive material such as indium tin oxide (ITO) or indium zinc oxide (IZO) so as to transmit light emitted from the light emitting element 520 toward an upper direction. The second cathode electrode 532 can be made of the same material as that of the first cathode electrode 531, and in this case, the cathode electrode 530, which includes the first and second cathode electrodes 531 and 532, can be viewed as a single layer. However, embodiments of the present disclosure are not limited thereto. For example, the light emitting display apparatus of the present disclosure can also be provided in a bottom emission mode or a dual emission mode. Thus, the material of the cathode electrode is not limited to the transparent conductive material. In such case, embodiments of the present disclosure can also solve the problem due to the particles introduced into the subpixel, as described later with reference to FIGS. 3A to 3C.

Since the cathode electrode 530, which includes the first cathode electrode 531 and the second cathode electrode 532, is made of a conductive material, the cathode electrode 530 can be electrically connected to the low potential power voltage line EVSSL to receive a low potential power voltage. Therefore, the anode electrode 510 can be supplied with a high potential power voltage, and the cathode electrode 530 can be supplied with a low potential power voltage lower than the high potential power voltage. Consequently, a current flows in the light emitting element 520 in a forward direction, and the first light emission area EA1 can normally emit light.

FIGS. 3A to 3C are cross-sectional views taken along line B-B′ shown in FIG. 1, illustrating a process of manufacturing a light emitting display apparatus according to an embodiment of the present disclosure. Further, FIG. 3A to FIG. 3C only show that the second light emission area EA2 is normally driven.

FIGS. 3A to 3C show a structure in which particles P introduced from the outside or generated during a process in the light emitting display apparatus according to FIGS. 1A, 1B and 2A to 2C are seated to form a short S, and thus show that a coating layer 600 is additionally formed. Hereinafter, differences from FIGS. 1A, 1B and 2A to 2C will be described.

Referring to FIG. 3A, a high potential power voltage line EVDDL, a data line DL, a first sensing line SL1, a buffer layer 150, a driving thin film transistor DTr, an anode electrode 510 and a bank 540 can be formed on a substrate 100.

The high potential power voltage line EVDDL, the data line DL, the buffer layer 150, the driving thin film transistor DTr, the anode electrode 510 and the bank 540 of FIG. 3A can include the same features as those disclosed in FIGS. 2A to 2C. As described above with reference to FIGS. 1A and 1B, the anode electrode 510 includes first and second divided electrodes 511 and 512. However, since FIGS. 3A to 3C show the second light emission area EA2, the second divided electrode 512 is only shown.

Further, in the non-light emission area NEA, the first bank 541 can be formed to cover the planarization layer 450 to reach an outer area rather than a position where the second sensing line SL2 is formed. Since the second bank 542 is formed in the outer area rather than the first bank 541, the second bank 542 may not overlap the second sensing line SL2. At this time, the particles P introduced from the outside or generated during the process can be seated on the second divided electrode 512.

Referring to FIG. 3B, a light emitting element 520 and a first cathode electrode 531 can be formed on the second divided electrode 512 and the bank 540. The light emitting element 520 and the first cathode electrode 531 of FIG. 3B can include the same features as those disclosed in FIGS. 2A to 2C.

In order to expose the second sensing line SL2, a second contact hole H2 passing through the buffer layer 150, the interlayer insulating layer 400, the planarization layer 450 and the first bank 541 can be formed. The first cathode electrode 531 can be extended in a direction in which the second contact hole H2 is formed, and can be electrically connected to the second sensing line SL2 through the second contact hole H2. A lower surface of the second contact hole H2 exposes the second sensing line SL2, and an inner surface of the second contact hole H2 is comprised of sides of the buffer layer 150, the interlayer insulating layer 400, the planarization layer 450 and the first bank 541.

Through the second sensing line SL2 electrically connected to the first cathode electrode 531, it is possible to check whether the second light emission area EA2 is normally driven. In detail, a voltage higher than a high potential power voltage supplied to the high potential power voltage line EVDDL can be supplied to the second sensing line SL2. In this case, since a higher voltage is supplied to the first cathode electrode 531 connected to the second sensing line SL2 rather than the second divided electrode 512 connected to the high potential power voltage line EVDDL, a voltage can be supplied to the light emitting element 520 in a reverse direction. When a voltage is supplied in a reverse direction, a current does not flow in the light emitting element 520 which is normally driven, whereby the light emitting element 520 does not emit light.

However, FIG. 3B of the present disclosure discloses a structure in which the light emitting element 520 and the first cathode electrode 531 are not normally formed on the second divided electrode 512 by particles P, a current can flow in the second light emission area EA2. In detail, the light emitting element 520 may not be formed as a single layer continuous on the second divided electrode 512 due to a step difference between the particles P and the second divided electrode 512. For example, a portion of the light emitting element 520 may not be continuous at a position adjacent to the particles P. Therefore, since the light emitting element 520 is not formed to cover an entire surface of the second divided electrode 512, a portion of the second divided electrode 512, which is adjacent to the particles P, can be exposed to the outside.

The first cathode electrode 531 is formed to cover the light emitting element 520, and can also cover an upper surface of the second divided electrode 512 exposed to the light emitting element 520. At this time, since the first cathode electrode 531 and the second divided electrode 512 are made of a conductive material, the first cathode electrode 531 and the second divided electrode 512 can be electrically connected to each other. For example, since a short S is formed by the contact between the first cathode electrode 531 and the second divided electrode 512, a current flows in the second light emission area EA2, and the second light emission area EA2 can partially emit light. Therefore, it is possible to check that the second light emission area EA2 is not normally driven, by sensing the current flowing to the second light emission area EA2.

In this case, a process for removing the short S between the first cathode electrode 531 and the second divided electrode 512 can be performed. In detail, a high voltage pulse can be applied to an end of the first cathode electrode 531 that is in contact with the second divided electrode 512. Due to the high voltage pulse, a degradation reaction occurs in the first cathode electrode 531 and the end of the first cathode electrode 531 can be melted. Therefore, the end of the first cathode electrode 531 can be physically spaced apart from the second divided electrode 512. However, embodiments of the present disclosure are not limited thereto. For example, the high voltage pulse may not be applied to an end of the first cathode electrode 531 that is in contact with the second divided electrode 512, such that the end of the first cathode electrode 531 remains in contact with the second divided electrode 512.

Therefore, a reverse voltage can be supplied to the light emitting element 520 through the second sensing line SL2, so that it is possible to check whether the second light emission area EA2 is normally driven by sensing the current flowing to the second light emission area EA2. In addition, when the second light emission area EA2 is not normally driven by the short S between the second divided electrode 512 and the first cathode electrode 531, the short S between the second divided electrode 512 and the first cathode electrode 531 can be removed. Further, since the cathode electrode 530 is formed as a double layer of the first and second cathode electrodes 531 and 532, a process for removing the short S can be performed only for the first cathode electrode 531. Therefore, since the first cathode electrode 531 having a thickness thinner than that of a conventional cathode electrode is melted, the possibility of removing the short S can be increased.

However, even though the end of the first cathode electrode 531 is physically spaced apart from the second divided electrode 512, a short may occur due to the contact of the first cathode electrode 531 with the second divided electrode 512 during a later process. To solve this issue, the coating layer 600 can be formed as shown in FIG. 3C.

Referring to FIG. 3C, the coating layer 600 can be formed to cover the entire surface of the first cathode electrode 531. The coating layer 600 can be formed by injecting an insulating material through an inkjet process. At this time, the second bank 542 serves as a partition for defining the area of the coating layer 600 so that the coating layer 600 can be formed inside the area surrounded by the second bank 542. The coating layer 600 is formed to cover the first bank 541, but may not be formed on the second bank 542. In addition, the coating layer 600 can be formed to fill the inside of the second contact hole H2.

In addition, the coating layer 600 can be formed to fill the short S. Therefore, water and oxygen can be prevented from being permeated into the light emitting element 520 through the short S, whereby reliability of the light emitting element 520 can be improved.

The second cathode electrode 532 can be provided on the coating layer 600, and can also be provided on the second bank 542. As described above with reference to FIGS. 1A and 1B, the second cathode electrode 532 can be electrically connected to the low potential power voltage line EVSSL to receive a low potential power voltage. However, since the first cathode electrode 531 is insulated from the second cathode electrode 532 by the coating layer 600, the first cathode electrode 531 cannot be supplied with a low potential power voltage. Therefore, although the anode electrode 510 is supplied with a high potential power voltage, the cathode electrode 530, which includes the first and second cathode electrodes 531 and 532, is not supplied with a low potential power voltage, whereby no current flows in the light emitting element 520 in a forward direction. For example, the second light emission area EA2 may not emit light.

Therefore, even though a short again may occur between the second divided electrode 512 and the first cathode electrode 531, since the short S is insulated by the coating layer 600, no current flows in the light emitting element 520 in a forward direction, and the second light emission area EA2 may not emit light. In addition, since the second cathode electrode 532 commonly provided in the first and second light emission areas EA1 and EA2 is insulated from the short S by the coating layer 600, the short S can be prevented from affecting the first light emission area EA1 during driving of the first light emission area EA1 that is normally formed.

Consequently, in the present disclosure, the light emission area EA is divided into the first and second light emission areas EA1 and EA2 so that the first light emission area EA1 that is normally formed can emit light and the second light emission area EA2 that is not normally formed may not emit light. In the related art, when a short occurs in a light emission area, a specific area in the entire area of the subpixel cannot emit light, so that a user can recognize a defect of the subpixel. However, in the present disclosure, in some situations, even though a short may occur in the second light emission area EA2, the first light emission area EA1 normally emits light, so that the subpixel is recognized as being normally driven, whereby a user may not recognize a defect of the subpixel.

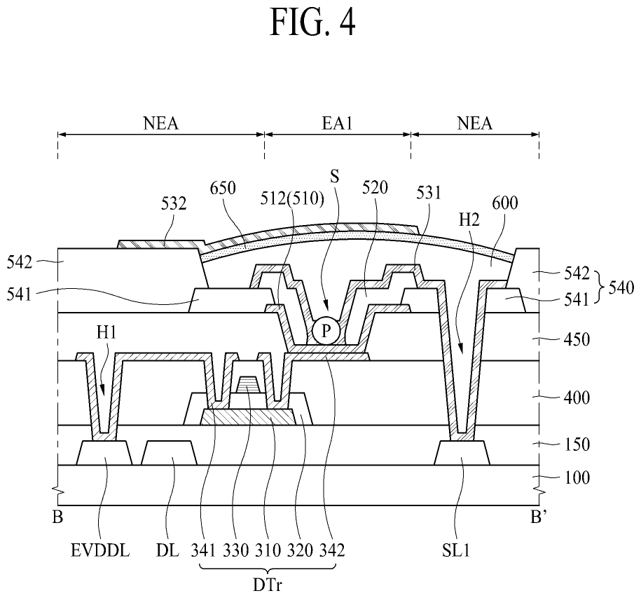

FIG. 4 is a cross-sectional view illustrating a light emitting display apparatus according to another embodiment of FIG. 3C.

Although FIG. 3C shows that the coating layer 600 is made of an insulating material, FIG. 4 shows a structure in which the coating layer 600 is made of a metal material. Hereinafter, differences from FIG. 3C will be described.

Referring to FIG. 4, the coating layer 600 can be formed to cover the entire surface of the first cathode electrode 531. The coating layer 600 can be formed by injecting a metal material of a liquid state through an inkjet process. At this time, the second bank 542 serves as a partition for defining the area of the coating layer 600, so that the coating layer 600 can be formed inside the area surrounded by the second bank 542. The coating layer 600 is formed to cover the first bank 541, but may not be formed on the second bank 542. In addition, the coating layer 600 can be formed to fill the inside of the second contact hole H2.

In addition, the coating layer 600 can be formed to fill the short S. Therefore, water and oxygen can be prevented from being permeated into the light emitting element 520 through the short S, whereby reliability of the light emitting element 520 can be improved.

An insulating layer 650 can be formed on the coating layer 600. The insulating layer 650 can be formed as a surface of the coating layer 600 that is oxidized. Since the second cathode electrode 532 is formed on the insulating layer 650, the second cathode electrode 532 can be insulated from the first cathode electrode 531. Therefore, as described above in FIG. 3C, the second light emission area EA2 may not emit light.

According to one or more embodiments of the present disclosure, the following advantageous effects can be obtained.

According to the present disclosure, the coating layer, which includes an insulating material, is formed on the subpixel into which particles are introduced, so that the subpixel can be normalized.

It will be apparent to those skilled in the art that the present disclosure described above is not limited by the above-described embodiments and the accompanying drawings and that various substitutions, modifications and variations can be formed in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display apparatus comprising:
a plurality of subpixels disposed on a substrate, each of the plurality of subpixels including first and second light emission areas and a non-light emission area disposed between the first and second light emission areas,
wherein one of the plurality of subpixels includes:
an anode electrode disposed on the substrate, and including first and second divided electrodes;
a light emitting element disposed on the anode electrode in the first and second light emission areas;
a bank disposed on the anode electrode in the non-light emission area; and
a cathode electrode disposed on the light emitting element and the bank, and
wherein the first divided electrode is disposed in the first light emission area, and the second divided electrode is disposed in the second light emission area.

2. The display apparatus of claim 1, wherein the non-light emission area is disposed to surround each of the first and second light emission areas.

3. The display apparatus of claim 1, wherein the first divided electrode and the second divided electrode are electrically connected with each other.

4. The display apparatus of claim 3, wherein the anode electrode further includes a connection portion disposed between the first divided electrode and the second divided electrode to electrically connect the first divided electrode with the second divided electrode.

5. The display apparatus of claim 1, wherein the cathode electrode is made of a transparent conductive material.

6. The display apparatus of claim 1, wherein the cathode electrode includes a first cathode electrode and a second cathode electrode disposed on the first cathode electrode, and
the first cathode electrode is divided into a plurality of areas, and is disposed in each of the first and second light emission areas.

7. The display apparatus of claim 6, wherein the first cathode electrode in the first light emission area and the second cathode electrode in the first light emission area are not in contact with each other, and are insulated from each other.

8. The display apparatus of claim 6, further comprising first and second sensing lines on the substrate in the non-light emission area,
wherein the first cathode electrode disposed in the first light emission area is electrically connected to the first sensing line, and
the first cathode electrode disposed in the second light emission area is electrically connected to the second sensing line.

9. The display apparatus of claim 8, wherein the second cathode electrode is disposed to not overlap with the first sensing line and the second sensing line, and is disposed to not electrically connected with the first sensing line and the second sensing line.

10. The display apparatus of claim 8, wherein the first cathode electrode is electrically connected to the first sensing line or the second sensing line through a contact hole, and
wherein a coating layer disposed between the first cathode electrode and the second cathode electrode is disposed to fill the contact hole.

11. The display apparatus of claim 6, wherein a coating layer is disposed between the first cathode electrode and the second cathode electrode, which are disposed in the first light emission area.

12. The display apparatus of claim 11, wherein in the first light emission area, the first cathode electrode is electrically connected with the first divided electrode.

13. The display apparatus of claim 11, wherein the bank includes a first bank surrounding each of the first and second divided electrodes and a second bank surrounding the first bank, and
the coating layer is disposed inside an area surrounded by the second bank, and covers the entire first cathode electrode disposed in the first light emission area.

14. The display apparatus of claim 13, wherein the second bank has a height higher than that of the first bank.

15. The display apparatus of claim 8, wherein the bank includes a first bank surrounding each of the first and second divided electrodes and a second bank surrounding the first bank, and
wherein the second bank is disposed in an outer area rather than the first and second sensing lines.

16. The display apparatus of claim 11, wherein a portion of the light emitting element is not continuous in the first light emission area.

17. The display apparatus of claim 11, wherein the coating layer is made of an insulating material.

18. The display apparatus of claim 11, wherein the coating layer is made of metal, and a surface of the coating layer is oxidized to form an insulating layer.
